(19) United States
(12) Patent Application Publication
(10) Pub. No.: US 2026/0128106 A1
(43) Pub. Date: May 7, 2026

(54) NON-VOLATILE MEMORY DEVICE, METHOD OF OPERATING THE SAME, AND STORAGE DEVICE INCLUDING THE SAME

(71) Applicant: Samsung Electronics Co., Ltd., Suwon-si (KR)

(72) Inventor: SANG-IN PARK, Suwon-si (KR)

(21) Appl. No.: 19/330,758

(22) Filed: Sep. 16, 2025

(30) Foreign Application Priority Data
Nov. 6, 2024 (KR) 10-2024-0156447

(51) Int. Cl. G11C 16/30; G11C 5/06; G11C 16/04; G11C 16/10; G11C 16/26

(52) U.S. Cl. CPC G11C 16/30; G11C 5/063; G11C 16/0483; G11C 16/10; G11C 16/26

(57) ABSTRACT

A non-volatile memory device may include a memory cell array including a memory cell array including a plurality of first memory cells connected to a first wordline, a voltage generator configured to provide a plurality of integrity checking voltages to a first integrity checking line electrically connected to the first wordline, and a control logic circuit configured to receive a residual voltage of the first wordline from the first integrity checking line in response to provision of the plurality of integrity checking voltages to the first integrity checking line.

### CROSS-REFERENCE TO RELATED APPLICATION(S)

This application claims priority to and the benefit of Korean Patent Application No. 10-2024-0156447, filed in the Korean Intellectual Property Office on Nov. 6, 2024, the disclosure of which is incorporated herein by reference in its entirety.

### BACKGROUND OF THE INVENTION

### (a) Field of the Invention

The present disclosure relates to a non-volatile memory device, a method of operating the non-volatile memory device, and a storage device including the non-volatile memory device.

### (b) Description of the Related Art

Semiconductor memory devices may be classified into volatile memory devices and non-volatile memory devices depending on whether stored data is lost when power is cut off.

A non-volatile memory device includes memory cells connected to wordlines and bitlines, and various types of voltages are applied to a plurality of wordlines while a program/read operation is performed on the memory cells. When the program/read operation is completed, a recovery operation is performed to discharge the wordlines, and if the recovery operation is not performed properly, it may cause disturbance to surrounding memory cells.

Particularly, some of a plurality of wordlines may have inherent defects and may not allow the recovery operation to be performed properly, and in order to ensure the reliability of the non-volatile memory device, bad wordlines need to be screened out.

### SUMMARY

An example embodiment provides a non-volatile memory device for selecting a bad wordline that is internally defective, and a method of operating the non-volatile memory device.

An example embodiment provides a non-volatile memory device for rapidly selecting a bad wordline without leaving residual voltage, a method of operating the non-volatile memory device, and a storage device including the non-volatile memory device.

According to an example embodiment, a non-volatile memory includes a memory cell array including a memory cell array including a plurality of first memory cells connected to a first wordline, a voltage generator configured to provide a plurality of integrity checking voltages to a first integrity checking line electrically connected to the first wordline, and a control logic circuit configured to receive a residual voltage of the first wordline from the first integrity checking line in response to provision of the plurality of integrity checking voltages to the first integrity checking line.

According to an example embodiment, a method of operating a non-volatile memory device includes performing a memory operation for a target wordline, providing a first integrity checking voltage to an integrity checking line electrically connected to an adjacent wordline disposed adjacent to the target wordline, in response to completion of the memory operation, performing a first charge sharing operation for sharing charge between a wordline capacitance of the adjacent wordline and a capacitance of the integrity checking line accumulated by the first integrity checking voltage, generating a first voltage variation value of a residual voltage of the adjacent wordline in response to the first charge sharing operation, and detecting a determination residual voltage for the adjacent wordline based on the first voltage variation value.

According to an example embodiment, a storage device includes a non-volatile memory device including a memory cell array including a plurality of first memory cells connected to a first wordline, and a control logic circuit configured to detect a determination residual voltage for the first wordline through a first integrity checking line electrically connected to the first wordline and output a status signal for the first wordline based on the determination residual voltage, and a storage controller configured to perform a replacement operation for the first wordline based on the status signal.

### BRIEF DESCRIPTION OF THE DRAWINGS

FIG. 1 is a block diagram illustrating a storage device according to an embodiment.

FIG. 2 is a block diagram illustrating a controller according to an embodiment.

FIG. 3 is a block diagram illustrating a non-volatile memory device according to an embodiment.

FIG. 4 illustrates a three-dimensional structure of a memory cell array according to an embodiment.

FIG. 5 illustrates the connection relationship of a wordline, an integrity checking line, a voltage generator, and a control logic according to an embodiment.

FIG. 6 is a circuit diagram showing a voltage variation value generator according to an embodiment.

FIG. 7 is a block diagram showing a voltage variation value generator according to an embodiment.

FIG. 8 is a flowchart for describing a method of operating a non-volatile memory device according to an embodiment.

FIG. 9 is a timing diagram for describing a method of operating a non-volatile memory device according to an embodiment.

FIGS. 10 to 16 illustrate a method of operating a non-volatile memory device according to example embodiments.

FIG. 17 is a block diagram illustrating a data storage device, which is an example of a storage device according to an embodiment.

FIG. 18 is a block diagram illustrating a computing system including a storage device according to an embodiment.

### DETAILED DESCRIPTION OF THE EMBODIMENTS

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

In addition, unless explicitly stated to the contrary, the word “comprise,” and variations such as “comprises” and “comprising,” should be understood to imply the inclusion of stated elements but not the exclusion of any other elements.

In addition, throughout the specification, when it is said that “one component is disposed adjacent to another component,” it means that one component and another component are disposed adjacent to each other so that no component the same as or similar to one component is disposed between one component and another component, or one component and another component are in contact with each other. For example, the adjacent disposition of the same or similar “X” and “Y” includes “X” and “Y” being adjacent so that no component the same as or similar to “X” is disposed between “X” and “Y,” or “X” and “Y” are in contact with each other.

It should be noted that if it is stated in the specification that one component is “connected,” “coupled” or “joined” to another component, a third component may be “connected,” “coupled,” and “joined” between the first and second components, although the first component may be directly connected, coupled, or joined to the second component. In addition, when a part is electrically coupled to another part, it includes not only cases where the two parts are directly connected, but also cases where they are connected with another element therebetween.

It should be further understood by those skilled in the art that if a specific number of an introduced claim recitation is intended, such an intent will be explicitly recited in the claim, and in the absence of such recitation no such intent is present. For example, to facilitate understanding, the following appended claims may contain usage of the introductory phrases “at least one” and “one or more” to introduce claim recitations. However, the use of such phrases should not be understood as a limitation described by the unambiguous article “one,” for one example.

Furthermore, in those instances where a convention analogous to “at least one of A, B, and C, etc.” is used, in general such a construction is intended in the sense in which one having skill in the art would understand the convention (e.g., “a system having at least one of A, B, and C” would include but not be limited to systems that have A alone, B alone, C alone, A and B together, A and C together, B and C together, and/or A, B, and C together, etc.). Alternatively, a disjunctive word and/or phrase presenting two or more alternative terms, whether in the description, claims, or drawings, should be understood as likely to include one of the terms, either of the terms, or both of the terms unless context dictates otherwise. For example, the phrase “A or B” should be typically understood to include the possibilities of “A” or “B” or “A and B.”

In this specification, “a module,” “a unit,” or “a part” perform at least one function or operation, and may be realized as hardware, such as a processor or integrated circuit, software that is executed by a processor, or a combination thereof.

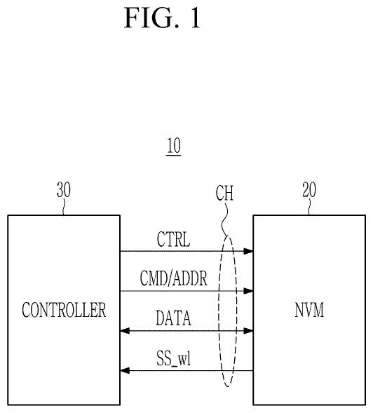

Referring to FIG. 1, a storage device 10 may include a storage controller 30 and a non-volatile memory device 20.

The storage controller 30 may transmit and receive signals to and from the non-volatile memory device 20 through a channel CH. The storage controller 30 may provide an address ADDR, a command CMD, and a control signal CTRL to the non-volatile memory device 20 and transmit and receive data DATA with the non-volatile memory device 20. The non-volatile memory device 20 may provide a wordline status signal SS_wl to the storage controller 30.

The storage controller 30 may control the non-volatile memory device 20 in response to a request from a host device (not shown). For example, the storage controller 30 may control the non-volatile memory device 20 to read data DATA stored in the non-volatile memory device 20 or write data DATA to the non-volatile memory device 20 in response to a data operation request received from the host device.

According to an embodiment, the storage controller 30 may transmit and receive the address ADDR, the command CMD, the control signal CTRL, the data DATA, and the wordline status signal SS_wl through an input/output line corresponding to the channel CH. The input/output line may include a command address line and a data line separated from each other. Through the command address line, the address ADDR and the command CMD may be provided to the non-volatile memory device 20, and the wordline status signal SS_wl may be provided to the storage controller 30. Each address ADDR, command CMD, and wordline status signal SS_wl may be distinguished through a header signal output to the command address line. Through the data line, the data DATA may be transmitted and received between the storage controller 30 and the non-volatile memory device 20.

The storage controller 30 may control the non-volatile memory device 20 to perform program, read, and erase operations by providing the address ADDR, the command CMD, and the control signal CTRL to the non-volatile memory device 20. In the present disclosure below, program, read, and erase operations for memory cells in a non-volatile memory device are referred to as memory operations.

The non-volatile memory device 20 may perform a memory operation on the data DATA in response to signals received from the storage controller 30. The non-volatile memory device 20 may include at least one memory cell array. The memory cell array may include a plurality of memory cells disposed in regions where a plurality of wordlines and a plurality of bitlines intersect, and the plurality of memory cells may be non-volatile memory cells. The non-volatile memory device 20 may include NAND flash memory, vertical NAND (VNAND) flash memory, NOR flash memory, resistive random-access memory (RRAM), phase-change memory (PRAM), magnetoresistive random-access memory (MRAM), ferroelectric random-access memory (FRAM), spin transfer torque random-access memory (STT-RAM), etc., and a combination thereof.

The storage controller 30 may select a memory region including a wordline or memory block in the non-volatile memory device 20 as bad based on the received wordline status signal SS_wl, and replace the memory region selected as bad with another normal region, etc. The wordline status signal SS_wl may include address information of the target memory region and integrity determination of the memory region.

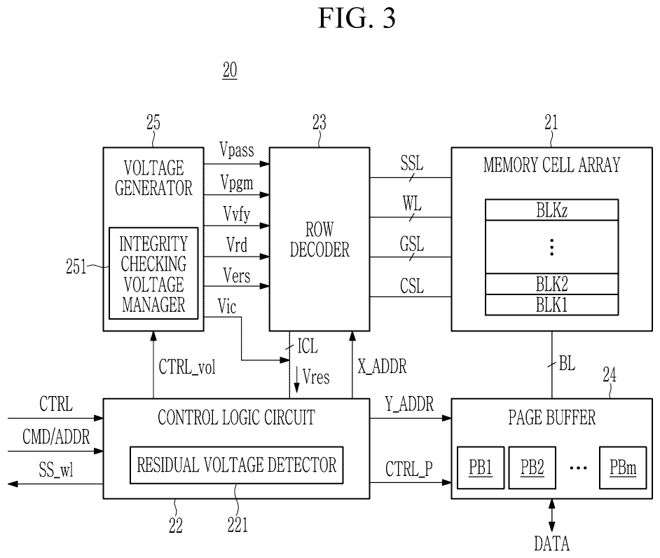

The non-volatile memory device 20 may detect a residual voltage for an adjacent wordline disposed adjacent to a target wordline of the memory operation and determine the integrity of the adjacent wordline based on the detected residual voltage after a predetermined time has passed after performing the memory operation. The non-volatile memory device 20 may output the wordline status signal SS_wl for a memory region that is a determination target based on an integrity determination. For example, the non-volatile memory device 20 may detect a residual voltage of a wordline adjacent to a target wordline of the program operation or read operation after a predetermined time has passed after performing a program operation or a read operation, and provide the wordline status signal SS_wl for the adjacent wordline to the storage controller 30 based on the detected residual voltage. In the present disclosure, the target wordline is a wordline selected by a row decoder 23 (FIG. 3) to be described later and connected to a memory cell that is a target of the memory operation.

The non-volatile memory device 20 may directly detect the residual voltage of the wordline after a certain period of time after performing the memory operation, and based on this, it may quickly determine the integrity of a portion of the memory region internally.

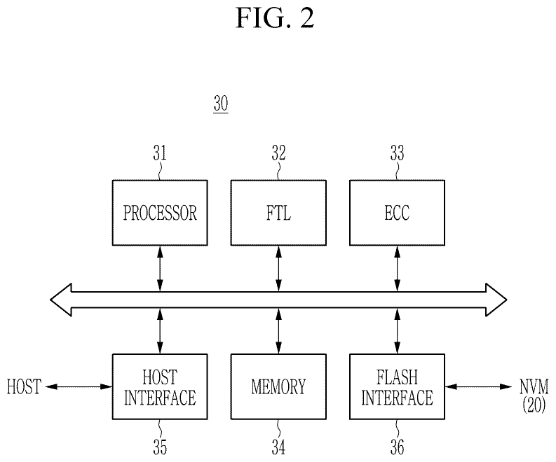

FIG. 2 is a block diagram illustrating a controller according to an embodiment.

Referring to FIGS. 1 and 2, the storage controller 30 may include a processor 31, a flash translation layer 32, an error correction code ECC engine 33 (hereinafter referred to as ECC engine), a memory 34, a host interface 35, and a memory interface 36.

The processor 31 may control various operations of the storage controller 30. The memory 34 may operate as a buffer memory, cache memory, or operating memory of the processor 31. Depending on the embodiment, the memory 34 may include dynamic random access memory (DRAM), static random access memory (SRAM), etc., but the present invention is not limited thereto.

The flash translation layer 32 (hereinafter referred to as FTL) may provide an interface between a host device (not shown) and the non-volatile memory device 20 so that the non-volatile memory device 20 may be used efficiently. According to an embodiment, the FTL 32 may perform address mapping operations, garbage collection operations, wear leveling operations, read reclaim operations, re-mapping and mapping-out operations for bad regions, etc. as a memory management module.

The FTL 32 may mark the memory region as bad and map out a bad memory region based on the wordline status signal SS_wl received from the non-volatile memory device 20. For example, the FTL 32 may mark a target memory block as a bad block and map it out based on the received wordline status signal SS_wl, or change mapping information for the target wordline based on the received wordline status signal SS_wl. The FTL 32 may perform a wear leveling operation during the mapping out process to move data stored in the bad memory region to another normal region.

The FTL 32 may be provided in hardware form as a dedicated circuit, but is not limited thereto. According to an embodiment, the FTL 32 may be provided in software form, and when provided in software form, may be loaded into the memory 34 and operated by the processor 31. For example, the FTL 32 and an address mapping table (not shown) may be stored in the memory 34. The FTL 32 and the address mapping table (not shown) stored in the memory 34 may be operated by the processor 31.

An ECC engine 33 may use various error correction techniques to correct errors in data DATA input/output from the non-volatile memory device 20. However, error correction for data DATA may not be possible by the ECC engine 33, such as when the overall distribution of the memory cell is changed due to disturbance by an adjacent wordline. In such cases, the FTL 32 may mark adjacent wordlines as bad and perform a mapping out operation.

Communication may be made between a host device (not shown) and the storage controller 30 through the host interface 35. For example, the host interface 35 may include various interfaces such as universal serial bus (USB), multimedia card (MMC), peripheral component interconnection (PCI), PCI-express (PCI-E), advanced technology attachment (ATA), Serial-ATA, Parallel-ATA, small computer small interface (SCSI), enhanced small disk interface (ESDI), integrated drive electronics (IDE), mobile industry processor interface (MIPI), NVMe, etc. The storage controller 30 may communicate with the non-volatile memory device 20 through a memory interface 26.

Referring to FIGS. 1 and 3, the non-volatile memory device 20 may include a memory cell array 21, a control logic circuit 22, a row decoder 23, a page buffer circuit 24, and a voltage generator 25. Although not shown in FIG. 3, depending on the embodiment, the non-volatile memory device 20 may further include a memory interface circuit, and may also further include a column logic circuit, a pre-decoder, a temperature sensor, a command decoder, an address decoder, and the like.

The memory cell array 21 may be connected to the page buffer circuit 24 through a plurality of bitlines BL and may be connected to the row decoder 23 through a plurality of wordlines WL, a plurality of string select lines SSL, a plurality of ground select lines GSL, and a common source line CSL.

The memory cell array 21 may include a plurality of memory blocks (BLK1 to BLKz) including a plurality of memory cells. Hereinafter, z may be an integer greater than or equal to 2. For example, the memory cells may be flash memory cells. Hereinafter, the embodiments of the present disclosure will be described in detail by taking as an example a case where a plurality of memory cells are NAND flash memory cells. However, the present disclosure is not limited thereto, and in an embodiment, the plurality of memory cells may be resistive memory cells such as resistive RAM (ReRAM), phase change RAM (PRAM), ferroelectric RAM (FRAM), or magnetic RAM (MRAM).

Each of the memory cells included in the memory cell array 21 may store at least one bit. For example, the memory cell may be a single-level cell (hereinafter, SLC) that stores 1-bit data. As another example, the memory cell may be a multi-level cell (hereinafter, MLC) that stores 2-bit data. As another example, the memory cell may be a triple-level cell (hereinafter, TLC) that stores 3-bit data. As another example, the memory cell may be a quad-level cell (or quadruple-level cell; hereinafter, QLC) that stores 4-bit data. However, the technical idea of the present disclosure is not limited thereto.

The plurality of memory blocks BLK1 to BLKz may include at least one of a single-level cell block including SLCs, a multi-level cell block including MLCs, a triple-level cell block including TLCs, and a quad-level cell block including QLCs. Some of the memory blocks included in the memory cell array 21 may be single-level cell blocks, and other blocks may be multi-level cell blocks or triple-level cell blocks.

When an erase voltage Vers is applied to the memory cell array 21, the plurality of memory cells are in an erased state, and when a program voltage Vpgm is applied to the memory cell array 21, the plurality of memory cells may be in a programmed state. In this case, each memory cell may have an erased state and at least one programmed state distinguished according to a cell threshold voltage. For example, if the memory cell is a TLC that stores 3-bit data, the memory cell may have an erased state and one of first to seventh states, but the type of the memory cell of the present disclosure may be SLC, MLC, or QLC and is not limited to the above examples.

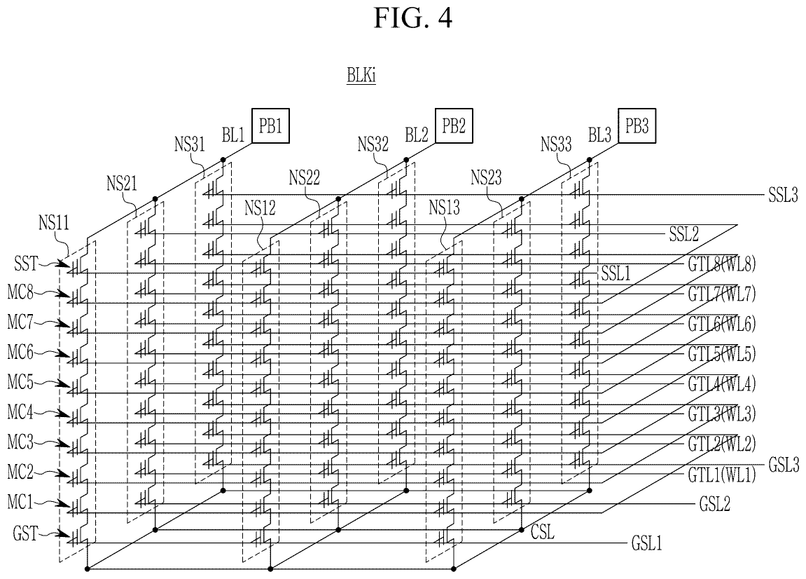

In an embodiment, the memory cell array 21 may include a three-dimensional memory cell array, but the technical idea of the present disclosure is not limited thereto and may be a two-dimensional memory cell. The three-dimensional memory cell array may include a plurality of cell strings, and each of the cell strings may include memory cells respectively connected to a plurality of wordlines vertically stacked on a substrate. A detailed description of the structure of the three-dimensional memory cell array is provided later in the description of FIG. 4.

The control logic circuit 22 may control various operations within the non-volatile memory device 20. The control logic circuit 22 may output various control signals in response to the command CMD, the address ADDR, and/or the control signal CTR received from the storage controller 30. The control logic circuit 22 may output a control signal to write or program data DATA into the memory cell array 21, read data DATA from the memory cell array 21, or erase data stored in the memory cell array 21. For example, the control logic circuit 22 may output a voltage control signal CTRL_vol, a row address X-ADDR, a column address Y-ADDR, and a page buffer control signal CTRL_P.

Various control signals output from the control logic circuit 22 may be provided to the voltage generator 25, the row decoder 23, and the page buffer circuit 24. The control logic circuit 22 may provide the voltage control signal CTRL_vol to the voltage generator 25.

According to an embodiment, the control logic circuit 22 may generate the voltage control signal CTRL_vol to control the generation of a program voltage Vpgm, a verify voltage Vvfy, and a pass voltage Vpass provided to a wordline WL of the memory cell array 21 in a program operation. When the plurality of memory cells are programmed, the control logic circuit 22 may control various operations within the non-volatile memory 20 so that at least one program loop is performed sequentially. In the program loop, the control logic circuit 22 may control the plurality of memory cells to receive at least one program voltage Vpgm and at least one verify voltage Vvfy through a selected target wordline among a plurality of wordlines WL, and to receive a pass voltage Vpass to an unselected wordline within the same memory block.

The control logic circuit 22 may generate the voltage control signal CTRL_vol to control the generation of a read voltage Vrd and the pass voltage Vpass provided to the wordline WL of the memory cell array 21 in a read operation. When the plurality of memory cells are read, the control logic circuit 22 may control the plurality of memory cells to receive at least one read voltage Vrd through the target wordline among the plurality of wordlines WL and to receive the pass voltage Vpass to an unselected wordline within the same memory block.

The control logic circuit 22 may generate the voltage control signal CTRL_vol to control the generation of an integrity checking voltage Vic provided to an integrity checking line ICL electrically connected to the wordline WL after a certain period of time after completing a program operation or a read operation. After a certain amount of time has passed after the plurality of memory cells are programmed or read, the control logic circuit 22 may control at least some of a plurality of integrity checking lines ICL to be provided with the integrity checking voltage Vic. For example, when a program operation or a read operation for the target wordline among the plurality of wordlines WL is completed, the control logic circuit 22 may control the integrity checking line ICL for an unselected wordline to be provided with the integrity checking voltage Vic.

The control logic circuit 22 may include a residual voltage detector 221. The residual voltage detector 221 may be electrically connected to the row decoder 23 and the plurality of wordlines WL through the plurality of integrity checking lines ICL. Each of the plurality of integrity checking lines ICL may be electrically connected to the corresponding plurality of wordlines WL through the row decoder 23.

In response to the integrity checking voltage Vic being provided to the integrity checking line ICL, the residual voltage detector 221 may receive a residual voltage Vres of the wordline WL through the integrity checking line ICL, and detect a determination residual voltage based on the residual voltage Vres to determine the integrity of the wordline WL. The residual voltage detector 221 may determine the integrity of the wordline WL based on the determination residual voltage, and may provide the wordline status signal SS_wl to the storage controller 30 based on the determination.

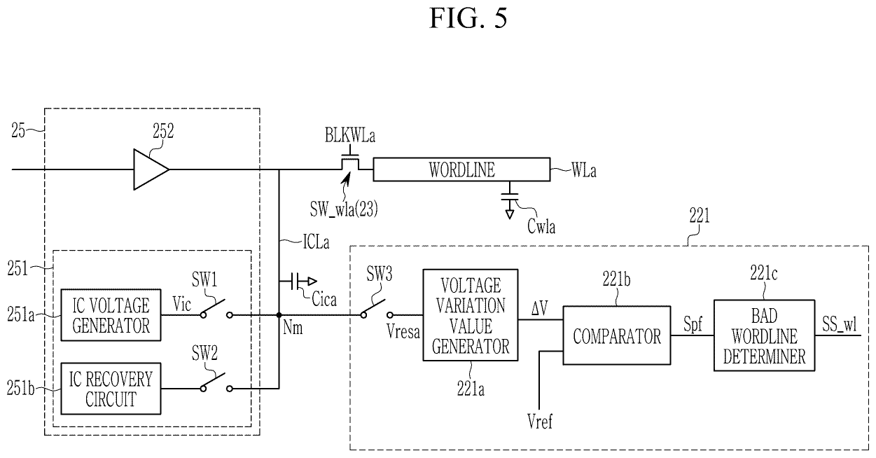

A detailed description of the connection relationship between the residual voltage detector 221, the row decoder 23, the plurality of integrity checking lines ICL, the plurality of wordlines WL and the configuration of the residual voltage detector 221 will be described later in the description of FIG. 5.

The voltage generator 25 may be connected to the memory cell array 21 through the row decoder 23 and the plurality of wordlines WL. The voltage generator 25 may generate various types of voltages for performing program, read, and erase operations on the memory cell array 21 based on the voltage control signal CTRL_vol. The voltage generator 25 may generate, for example, the program voltage Vpgm, the verify voltage Vvfy, the read voltage Vrd, the pass voltage Vpass, and the erase voltage Vers. Depending on the embodiment, the pass voltage Vpass may be a voltage applied to an unselected wordline during a read or verify operation.

The program voltage Vpgm, verify voltage Vvfy, read voltage Vrd, etc. generated by the voltage generator 25 may be provided to the target wordline selected from among the plurality of wordlines WL. The target wordline may be at least one wordline selected by the row address X-ADDR.

The voltage generator 25 may include an integrity checking voltage manager 251. After a certain amount of time has passed after the plurality of memory cells are programmed or read, the integrity checking voltage manager 251 may provide the integrity checking voltage Vic to the integrity checking line ICL for a wordline that is not selected by the row address X-ADDR.

The integrity checking voltage manager 251 may provide a plurality of integrity checking voltages Vic to the integrity checking line ICL. According to an embodiment, the integrity checking voltage manager 251 may provide the plurality of integrity checking voltages Vic in the order of high voltage to low voltage to the integrity checking line ICL. According to an embodiment, the integrity checking voltage manager 251 may provide the plurality of integrity checking voltages Vic to the integrity checking line ICL at regular time intervals, and may ground the integrity checking line ICL after providing each integrity checking voltage Vic.

A detailed description of the connection relationship between the integrity checking voltage manager 251, the row decoder 23, the plurality of integrity checking lines ICL, the plurality of wordlines WL and the configuration of the integrity checking voltage manager 251 will be described later in the description of FIG. 5.

The row decoder 23 may select a specific wordline among the wordlines WL in response to the row address X-ADDR received from the control logic circuit 22.

Specifically, during a program operation, the row decoder 23 may apply the program voltage Vpgm and the verify voltage Vvfy to a selected wordline during one program loop. The row decoder 23 may apply the pass voltage Vpass to the remaining unselected wordlines during a program operation. During a read operation, the row decoder 23 may apply the read voltage Vrd to a selected wordline and may apply the pass voltage Vpass to the remaining unselected wordlines. Additionally, the row decoder 23 may select some of the string select lines SSL or some of the ground select lines GSL in response to the row address X-ADDR.

In response to the integrity checking voltage Vic being provided to the integrity checking line ICL, the row decoder 23 may control the electrical connection between the integrity checking line ICL and the corresponding wordline WL. For example, while the integrity checking voltage Vic is provided to the integrity checking line ICL, the row decoder 23 may block the connection between the integrity checking line ICL and the wordline WL, and after the integrity checking voltage Vic is provided to the integrity checking line ICL, the row decoder 23 may electrically connect the integrity checking line ICL and the wordline WL.

The page buffer circuit 24 may be connected to the memory cell array 21 through a plurality of bitlines BL. The page buffer circuit 24 may select some bitlines among the plurality of bitlines BL in response to the column address Y-ADDR received from the control logic circuit 22. During a read operation, the page buffer circuit 24 may operate as a sense amplifier to sense the data DATA stored in the memory cell array 21. Meanwhile, during the program operation, the page buffer circuit 24 operates as a write driver and may input data DATA to be stored in the memory cell array 21. The page buffer circuit 24 may store data DATA read from the memory cell array 21 or data DATA to be written to the memory cell array 21.

The page buffer circuit 24 may include a plurality of page buffers PB1 to PBm each connected to a plurality of bitlines BL. Hereinafter, m may be an integer greater than or equal to 2. The plurality of page buffers PB1 to PBm may be disposed corresponding to each bitline, and each page buffer may include a plurality of latch circuits. Hereinafter, the page buffer circuit will be defined as including a page buffer connected to each of the bitlines. However, the embodiments of the present disclosure may have terms defined differently—for example, a page buffer may be provided corresponding to the plurality of bitlines, and a unit of configuration disposed corresponding to each bitline may be defined as a page buffer unit.

The non-volatile memory device 20 may receive the residual voltage Vres from the wordline WL to which the pass voltage Vpass is applied during a program operation or a read operation through the integrity checking line ICL, the residual voltage detector 221, and the integrity checking voltage manager 251. The non-volatile memory device 20 may internally quickly determine the recovery performance and integrity of the wordline WL based on the received residual voltage Vres.

FIG. 4 illustrates a three-dimensional structure of a memory cell array according to an embodiment.

Referring to FIGS. 3 and 4, each of the plurality of memory blocks BLK1 to BLKz may be represented by an equivalent circuit of a memory block BLKi of FIG. 4, as illustrated. The memory block BLKi of FIG. 4 may be any one of the plurality of memory blocks BLK1 to BLKz of FIG. 3 and represents a three-dimensional memory block formed in a three-dimensional structure on a substrate. For example, a plurality of memory NAND strings included in the memory block BLKi may be formed in a direction perpendicular to the substrate.

The memory block BLKi may include a plurality of memory NAND strings NS11, NS21, NS31, NS12, NS22, NS32, NS13, NS23 and NS33 connected between a plurality of bitlines BL1, BL2, and BL3 and the common source line CSL. Each of the plurality of memory NAND strings NS11, NS21, NS31, NS12, NS22, NS32, NS13, NS23 and NS33 may include a string select transistor SST, a plurality of memory cells MC1, MC2, . . . , MC8, and a ground select transistor GST. In FIG. 2, each of the plurality of memory NAND strings NS11, NS21, NS31, NS12, NS22, NS32, NS13, NS23 and NS33 is illustrated as including eight memory cells MC1, MC2, . . . , MC8, but is not necessarily limited thereto.

The string select transistors SST may be connected to corresponding string select lines SSL1, SSL2, and SSL3. Each of the plurality of memory cells MC1, MC2, . . . , and MC8 may be connected to corresponding gate lines GTL1, GTL2, . . . , and GTL8. The gate lines GTL1, GTL2, . . . , and GTL8 may correspond to first to eighth wordlines WL1, WL2, . . . , and WL8, respectively, included in a plurality of wordlines WL, and some of the gate lines GTL1, GTL2, . . . , and GTL8 may correspond to dummy wordlines. The ground select transistor GST may be connected to the corresponding ground select lines GSL1, GSL2, and GSL3. The string select transistor SST may be connected to the corresponding bitlines BL1, BL2, and BL3, and the ground select transistor GST may be connected to the common source line CSL. Each of the bitlines BL1, BL2, and BL3 may be connected to a corresponding page buffer PB1, PB2, and PB3. Each of the page buffers PB1, PB2, and PB3 may be a page buffer among the plurality of page buffers PB1 to PBm.

Wordlines of the same height (e.g., WL1) are commonly connected, and the ground select lines GSL1, GSL2, and GSL3 and the string select lines SSL1, SSL2, and SSL3 may be separated, respectively. In FIG. 4, the memory block BLKi is illustrated as being connected to eight gate lines GTL1, GTL2, . . . , and GTL8 and three bitlines BL1, BL2, and BL3, but it is not necessarily limited thereto.

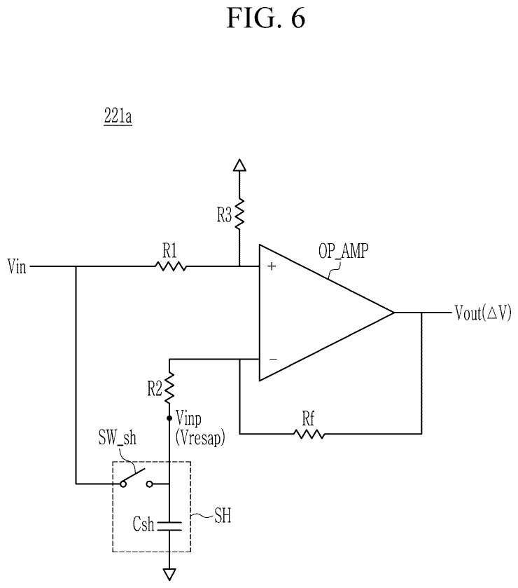

FIG. 5 illustrates the connection relationship of a wordline, an integrity checking line, a voltage generator, and a control logic circuit according to an embodiment. FIG. 6 is a circuit diagram showing a voltage variation value generator according to an embodiment. Specifically, FIG. 5 illustrates the configuration and connection relationship of the integrity checking voltage manager 251 and the residual voltage detector 221 based on one wordline WLa among the plurality of wordlines WL of FIGS. 3 and 4 and an integrity checking line ICLa corresponding to the wordline WLa. Similarly, the integrity checking line ICLa may be one integrity checking line corresponding to the wordline WLa among the plurality of integrity checking lines ICL of FIG. 3.

Referring to FIG. 1 and FIG. 3 to FIG. 6, the integrity checking line ICLa may be connected to the integrity checking voltage manager 251 and the residual voltage detector 221 of the voltage generator 25 through a connection node Nm, and may be connected to the wordline WLa through a wordline switch SW_wla of the row decoder 23. Additionally, the integrity checking line ICLa may individually include an integrity checking capacitance Cica having a parasitic capacitance. The integrity checking capacitance Cica may be formed between the integrity checking line ICLa and a ground voltage (e.g., GND or Vss). Herein, the integrity checking capacitance Cica is not a component that physically exists in the integrity checking line ICLa, and is a parasitic capacitance that exists in the integrity checking line ICLa.

The wordline WLa may be electrically connected to the integrity checking line ICLa and a driving driver 252 of the voltage generator (25) through the wordline switch SW_wla. The wordline switch SW_wla may be opened and closed by a wordline block signal BLKWLa, and according to an embodiment, the wordline block signal BLKWLa may be determined by the row address X-ADDR. Depending on the embodiment, the wordline switch SW_wla may be, but is not limited to, a high-voltage transistor. The driving driver 252 may provide the program voltage Vpgm, the verify voltage Vvfy, the read voltage Vrd, the pass voltage Vpass, and the erase voltage Vers to drive a memory operation to the wordline WLa.

The wordline WLa may individually include a wordline capacitance Cwla having a parasitic capacitance. The wordline capacitance Cwla is formed between the wordline WLa and the ground voltage. Herein, the wordline capacitance Cwla is not a component that physically exists in the wordline WLa, and is a parasitic capacitance that exists in the wordline WLa. The ratio of the capacitance of the wordline capacitance Cwla to the capacitance of the integrity checking capacitance Cica may be x to 1. The x may be a real number in the range of 50 to 150, preferably 75 to 125. For example, in response to the closing of the wordline switch SW_wla, a charge may be shared between the wordline capacitance Cwla and the integrity checking capacitance Cica, or a residual voltage Vresa of the wordline capacitance Cwla may be provided to the residual voltage detector 221. During charge sharing, the variation in the voltage charged to the wordline capacitance Cwla may be smaller than the variation of the voltage charged to the integrity checking capacitance Cica.

The integrity checking voltage manager 251 may include an integrity checking voltage generator 251a, an integrity checking line recovery circuit 251b, a first switch SW1, and a second switch SW2.

The integrity checking voltage generator 251a may be connected to the connection node Nm of the integrity checking line ICLa through the first switch SW1. By opening and closing the first switch SW1, the electrical connection between the integrity checking voltage generator 251a and the integrity checking line ICLa may be controlled. Depending on an embodiment, the opening and closing of the first switch SW1 may be controlled by the control logic circuit 22. The first switch SW1 may be, but is not limited to, a high-voltage transistor.

The integrity checking voltage generator 251a may provide the plurality of integrity checking voltages Vic to the integrity checking line ICLa in response to the first switch SW1 being closed. In response to the provision of the integrity checking voltage Vic, the integrity checking capacitance Cica may be charged.

The integrity checking voltage generator 251a may provide the plurality of integrity checking voltages Vic to the integrity checking line ICLa. Depending on an embodiment, the integrity checking voltage generator 251a may provide the plurality of integrity checking voltages Vic in order of high voltage to low voltage to the integrity checking line ICLa.

The integrity checking line recovery circuit 251b may be connected to the connection node Nm of the integrity checking line ICLa through the second switch SW2. By opening and closing the second switch SW2, the electrical connection between the integrity checking line recovery circuit 251b and the integrity checking line ICLa may be controlled. Depending on an embodiment, the opening and closing of the second switch SW2 may be controlled by the control logic circuit 22.

The integrity checking line recovery circuit 251b may ground the integrity checking line ICLa in response to the second switch SW2 being closed. By grounding the integrity checking line ICLa, the integrity checking capacitance Cica may be discharged.

The residual voltage detector 221 may include a third switch SW3, a voltage variation value generator 221a, a comparator 221b, and a bad wordline determiner 221c.

The voltage variation value generator 221a may be connected to the connection node Nm of the integrity checking line ICLa through the third switch SW3. By opening and closing the third switch SW3, the electrical connection between the voltage variation value generator 221a and the integrity checking line ICLa may be controlled. Depending on an embodiment, the opening and closing of the third switch SW3 may be controlled by the control logic circuit 22 itself by an internal operation of the control logic circuit 22. The third switch SW3 may be, but is not limited to, a high-voltage transistor. The voltage variation value generator 221a may receive the residual voltage Vresa of the wordline WLa through the wordline WLa and the integrity checking line ICLa in response to the closing of the third switch SW3.

The voltage variation value generator 221a may generate a voltage variation value ΔV of the residual voltage Vresa in response to charge sharing of the wordline capacitance Cwla. According to an embodiment, the voltage variation value generator 221a may generate the voltage variation value ΔV between the residual voltage Vresa received before providing the integrity checking voltage Vic and the residual voltage Vresa received after providing the integrity checking voltage Vic.

Referring to FIG. 6 as an example, the voltage variation value generator 221a is an analog circuit and may include an operational amplifier OP_AMP, a sample hold circuit SH, and a plurality of resistors R1 to R3, and Rf.

A positive input terminal of the operational amplifier OP_AMP may be connected to one end of a first resistor R1 and one end of a third resistor R3, and the positive input terminal of the operational amplifier OP_AMP may be connected to an input terminal to which an input voltage Vin is provided through the first resistor R1. The other terminal of the third resistor R3 may be grounded.

A negative input terminal of the operational amplifier OP_AMP may be connected to one end of a second resistor R2 and one end of a feedback resistor Rf, and the negative input terminal of the operational amplifier OP_AMP may be connected to the sample hold circuit SH that provides a previous input voltage Vinp through the first resistor R1. The other end of the feedback resistor Rf may be connected to an output terminal of the operational amplifier OP_AMP.

The sample hold circuit SH may include a sample switch SW_sh and a hold capacitor Csh. One end of the sample switch SW_sh may be connected to an input terminal of the voltage variation value generator 221a, and the other end of the sample switch SW_sh may be connected between the second resistor R2 and the hold capacitor Csh. One end of the hold capacitor Csh may be connected to the other end of the sample switch SW_sh and the other end of the second resistor R2, and the other end of the hold capacitor Csh may be grounded. By controlling the opening and closing of the sample switch SW_sh, the previous input voltage Vinp may be charged and maintained at one end of the hold capacitor Csh.

If the input voltage Vin of the voltage variation value generator 221a is the residual voltage Vresa of the wordline WLa after the provision of the integrity checking voltage Vic, the previous input voltage Vinp may be a previous residual voltage Vresap of the wordline WLa before the provision of the integrity checking voltage Vic.

According to an embodiment, if all resistances of the plurality of resistors R1 to R3, Rf are the same, the voltage variation value generator 221a may output a voltage corresponding to the voltage difference between the previous input voltage Vinp and the input voltage Vin as an output voltage Vout. The voltage difference may be the voltage variation value ΔV between the previous residual voltage Vresap and the residual voltage Vresa as the input voltage Vin.

The voltage variation value generator 221a of FIG. 6 is an example circuit, and the technical idea of the present disclosure is not limited thereto.

The comparator 221b may output a pass/fail signal Spf by comparing the voltage variation value ΔV corresponding to the integrity checking voltage Vic with a predetermined reference voltage Vref (hereinafter referred to as reference voltage Vref). For example, if the voltage variation value ΔV is less than the reference voltage Vref, the comparator 221b may output a pass signal, and if the voltage variation value ΔV is greater than the reference voltage Vref, the comparator 221b may output a fail signal. The output of the pass/fail signal Spf of the comparator 221b as described above is an example, and the technical idea of the present disclosure is not limited thereto.

The comparator 221b and the bad wordline determiner 221c may receive a plurality of voltage variation values ΔV corresponding to the plurality of integrity checking voltages Vic and detect a determination residual voltage based on the plurality of voltage variation values ΔV. The bad wordline determiner 221c may determine the integrity of the wordline WLa based on the detected determination residual voltage and a predetermined threshold voltage Vth (hereinafter referred to as threshold voltage Vth). When the bad wordline determiner 221c determines that the wordline WLa is bad, the non-volatile memory device 20 may provide the wordline status signal SS_wl to the storage controller 30 through the bad wordline determiner 221c based on the determination of bad.

The non-volatile memory device 20 according to an embodiment may internally and directly detect the residual voltage Vresa of the wordline WLa through the integrity checking line ICLa, the residual voltage detector 221, and the integrity checking voltage manager 251. According to an embodiment, the non-volatile memory device 20 directly detects the residual voltage Vresa of the wordline WLa, and does not require a time to leave the residual voltage to check whether a disturbance has occurred in an adjacent wordline. The non-volatile memory device 20 may quickly internally determine the recovery integrity of the wordline WLa and efficiently screen out bad wordlines.

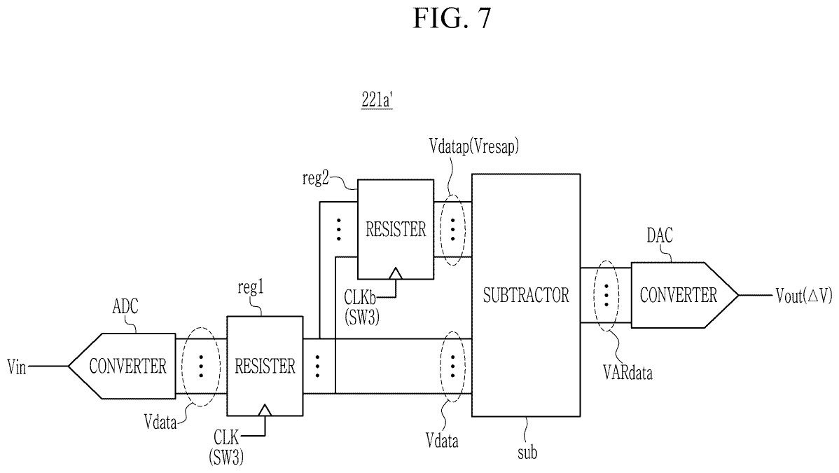

FIG. 7 is a block diagram showing a voltage variation value generator according to an embodiment. A voltage variation value generator 221a′ of FIG. 7 corresponds to the voltage variation value generator 221a of FIG. 6 and may be a different embodiment from the voltage variation value generator 221a. For ease of description below, the voltage variation value generator 221a′ will be described focusing on the differences between it and the voltage variation value generator 221a of FIG. 6.

Referring to FIGS. 5 and 7, the voltage variation value generator 221a′ is a digital circuit and may include an analog-to-digital converter ADC, a first register reg1, a second register reg2, a subtractor sub, and a digital-to-analog converter DAC.

The analog-to-digital converter ADC may receive the input voltage Vin and output input data Vdata based on the input voltage Vin. The output input data Vdata may be provided to the first register reg1.

The first register reg1 may latch the input data Vdata based on a clock signal CLK, and the latched input data Vdata may be provided to the subtractor sub and to the second register reg2. For example, the clock signal CLK may rise when the third switch SW3 is closed, and the first register reg1 may latch the input data Vdata as the third switch SW3 is closed.

The second register reg2 may receive the input data Vdata from the first register reg1 and latch an input data Vdatap based on an inverted clock signal CLKb. For example, the inverted clock signal CLKb may rise when the third switch SW3 opens, and the second register reg2 may latch the input data Vdata as the third switch SW3 opens.

When the first register reg1 performs a latch operation based on the rising of the clock signal CLK, the second register reg2 may not perform the latch operation. Therefore, while the first register reg1 latches the input data Vdata, the second register reg2 may latch the previous input data Vdatap.

The previous input data Vdatap latched in the second register reg2 may be provided to the subtractor sub.

If the input data Vdata latched in the first register reg1 is data about the residual voltage Vresa of the wordline WLa after the provision of the integrity checking voltage Vic, the previous input data Vdatap latched in the second register reg2 may be data about the previous residual voltage Vresap of the wordline WLa before the provision of the integrity checking voltage Vic.

The subtractor sub may receive and subtract the input data Vdata and the previous input data Vdatap to generate change data VARdata, and the change data VARdata may be provided to the digital-to-analog converter DAC and converted into an output voltage Vout. The change data VARdata corresponds to the voltage difference between the input data Vdata and the previous input data Vdatap, and the output voltage Vout may be the voltage variation value ΔV between the previous residual voltage Vresap and the residual voltage Vresa.

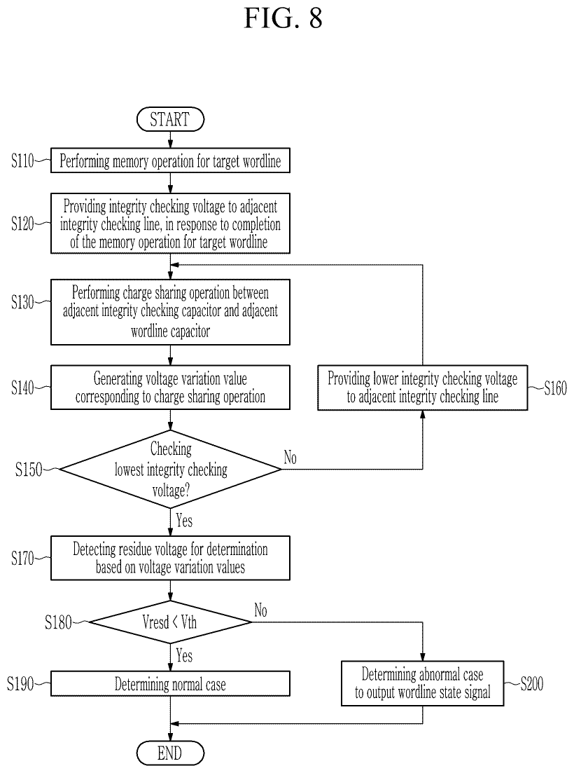

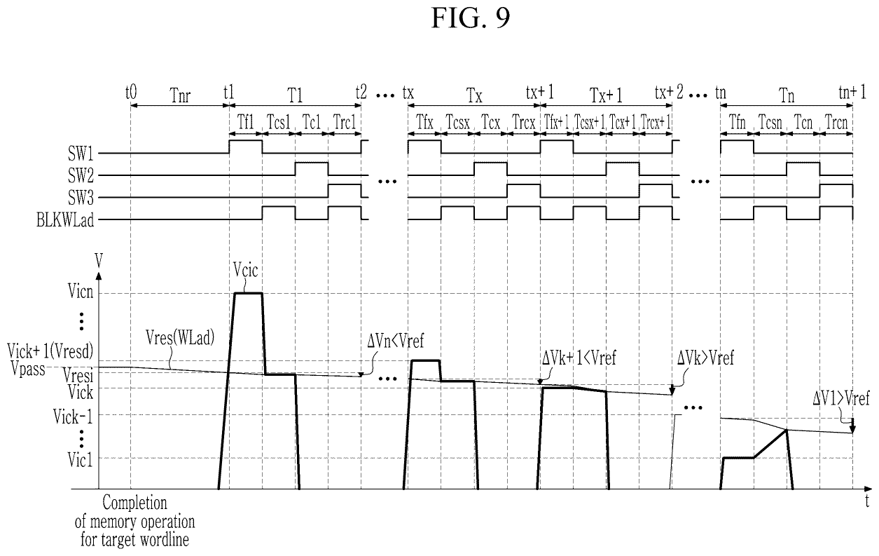

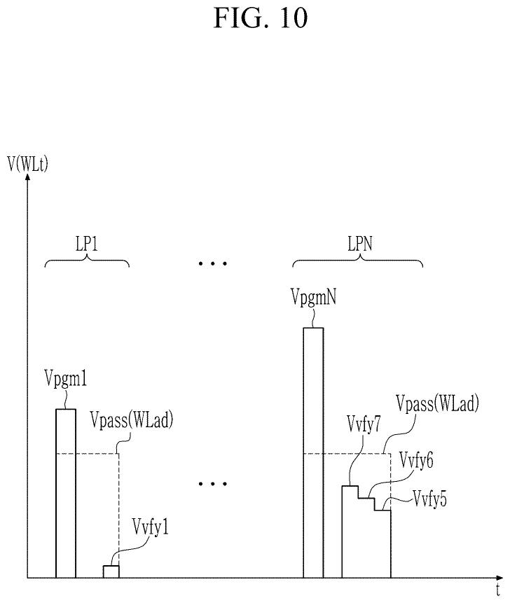

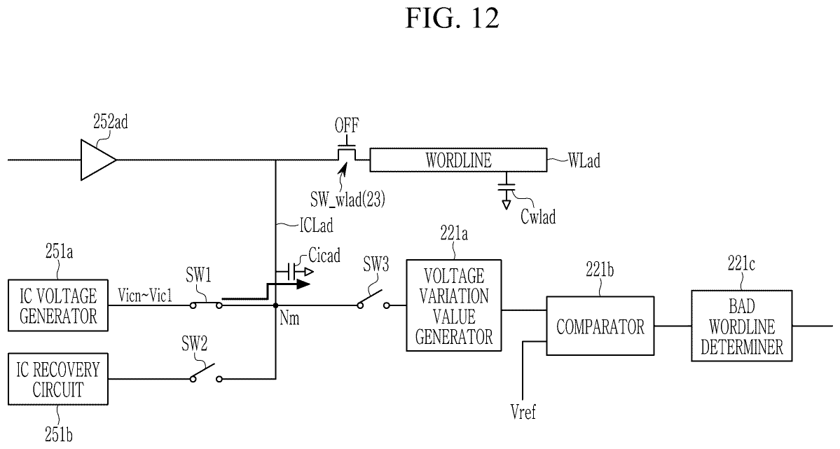

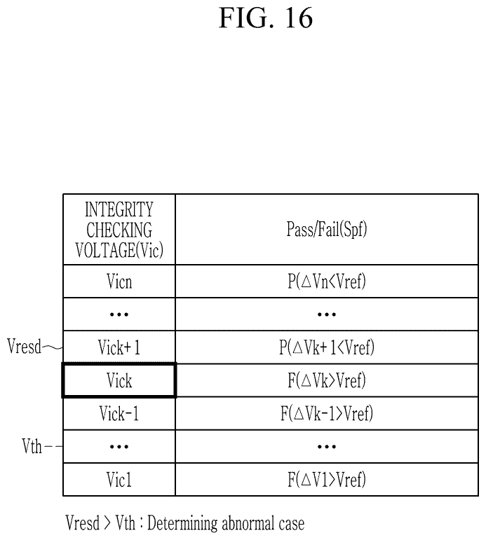

FIG. 8 is a flowchart to describe a method of operating a non-volatile memory device according to an embodiment. FIG. 9 is a timing diagram to describe a method of operating a non-volatile memory device according to an embodiment. FIGS. 10 to 16 illustrate a method of operating a non-volatile memory device according to example embodiments. Specifically, FIGS. 12 to 15 illustrate the flow of charge during an integrity determination for an adjacent wordline WLad, and FIG. 16 illustrates the integrity determination operation of the residual voltage detector 221 for the adjacent wordline WLad.

Referring to FIGS. 3, 5, 8, and 9, the non-volatile memory device 20 performs a memory operation (S110) for a target wordline WLt.

Before time t0, the non-volatile memory device 20 may perform a memory operation on a memory cell connected to the target wordline WLt, and for example, the non-volatile memory device 20 may perform a program operation or a read operation on the memory cell connected to the target wordline WLt.

With additional reference to FIG. 10, specifically, FIG. 10 illustrates voltages applied to the wordline WL when performing a program operation on the memory cell connected to the target wordline WLt. FIG. 10 illustrates voltages applied to the wordline WL assuming that the memory cell is TLC, but the technical idea of the present disclosure is not limited thereto.

While the program operation is being performed, the control logic circuit 22 may control the row decoder 23 and the voltage generator 25 so that the program voltage Vpgm and the verify voltage Vvfy are provided to the target wordline WLt in the form of a plurality of program loops LP1 to LPN. Herein, N may be an integer greater than or equal to 2.

Within one program loop, the row decoder 23 may apply the program voltage Vpgm to the target wordline WLt and apply at least one verify voltage Vvfy to the target wordline WLt to verify the programmed state. While the program voltage Vpgm and the verify voltage Vvfy are applied to the target wordline WLt, the row decoder 23 may be disposed adjacent to the target wordline WLt and provide the pass voltage Vpass to an unselected adjacent wordline WLad. Depending on the embodiment, the pass voltage Vpass may be lower than the program voltage Vpgm and higher than the verify voltage Vvfy.

Hereinafter, the integrity determination operation of the non-volatile memory device 20 of the present disclosure is described with a focus on the adjacent wordline WLad, but the method of operating the non-volatile memory device 20 of the present disclosure may be applied to a wordline that is not disposed adjacent to the target wordline WLt but receives the pass voltage Vpass in the memory operation of the target wordline WLt.

Referring to FIG. 10 as an example, in a first program loop LP1, the row decoder 23 may apply a first program voltage Vpgm1 to the target wordline WLt and apply a first verify voltage Vvfy1 to verify a first state to the target wordline WLt. In an Nth program loop LPN, the row decoder 23 may apply an Nth program voltage VpgmN to the target wordline WLt and apply fifth to seventh verify voltages Vvfy5 to Vvfy7 to verify fifth to seventh states to the target wordline WLt. The pass voltage Vpass may be lower than the first program voltage Vpgm1, which is the lowest among the program voltages Vpgm, and may be higher than the seventh verify voltage Vvfy7, which is the highest among the verify voltages Vvfy.

In FIG. 10, the program pass voltage for program voltages Vpgm1 to VpgmN and the verify pass voltage for verify voltages Vvfy1 to Vvfy7 are shown as matching, but they are not limited thereto and may be different from each other depending on the embodiment.

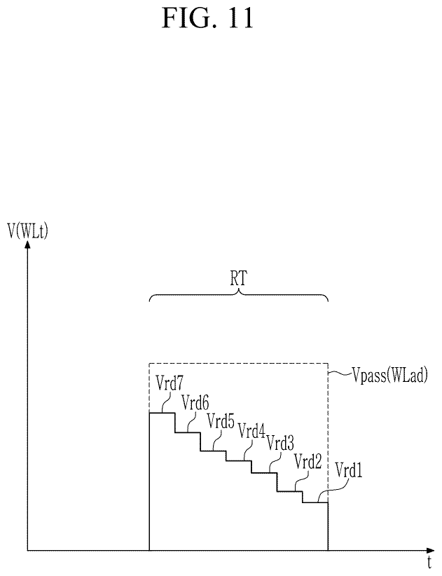

Additionally, referring to FIG. 11, FIG. 11 specifically illustrates voltages applied to the wordline WL when performing a read operation on a memory cell connected to the target wordline WLt. FIG. 11 illustrates voltages applied to the wordline WL assuming that the memory cell is TLC, but the technical idea of the present disclosure is not limited thereto.

During a read period RT in which a read operation is performed, the control logic circuit 22 may control the row decoder 23 and the voltage generator 25 so that first to seventh read voltages Vrd1 to Vrd7 for sensing the first to seventh states stored in the memory cell are applied in reverse order to the target wordline WLt. While the first to seventh read voltages Vrd1 to Vrd7 are applied to the target wordline WLt, the row decoder 23 is disposed adjacent to the target wordline WLt and may provide the pass voltage Vpass to the unselected adjacent wordline WLad. Depending on embodiments, the pass voltage Vpass may be higher than the seventh read voltage Vrd7, which is the highest of the read voltages Vrd.

Referring again to FIG. 9, at time t0, the non-volatile memory device 20 may complete a memory operation for the memory cell connected to the target wordline WLt. In some embodiments, in response to a memory operation of the target wordline WLt, the adjacent wordline WLad may have a residual voltage Vresad of the same potential as the pass voltage Vpass. After completion of the memory operation, the residual voltage Vresad of the adjacent wordline WLad may be discharged and recovered.

In response to completion of a memory operation for a memory cell connected to the target wordline WLt, the integrity checking voltage generator 251a provides the integrity checking voltage Vic to an adjacent integrity checking line ICLad (S120).

At time t1, when a predetermined normal recovery period Tnr has elapsed from time t0, the non-volatile memory device 20 may perform an integrity determination operation for the adjacent integrity checking line ICLad. While the non-volatile memory device 20 performs an integrity-determination operation for the adjacent integrity checking line ICLad, a write operation of the integrity checking voltage Vic, a charge sharing operation between an adjacent integrity checking capacitance Cicad and an adjacent wordline capacitance Cwlad, a discharge operation of the adjacent integrity checking capacitance Cicad, and a reception operation of the residual voltage Vresad for the adjacent wordline WLad may be repeatedly performed for each of first to Nth periods T1 to TN. Depending on an embodiment, the first to Nth periods T1 to TN may have equal time intervals. Herein, each of the adjacent integrity checking capacitance Cicad and the adjacent wordline capacitance Cwlad is not a component that physically exists in the adjacent integrity checking line ICLad and the adjacent wordline WLad, respectively, and is a parasitic capacitance that exists in the adjacent integrity checking line ICLad and the adjacent wordline WLad, respectively.

At time t1, the integrity checking voltage generator 251a may provide an nth integrity checking voltage Vicn, which is the highest voltage among a plurality of integrity checking voltages Vic1 to Vicn, to the adjacent integrity checking line ICLad.

With additional reference to FIG. 12, during a first voltage write period Tf1 of a first period T1, the first switch SW1 is closed, so that a write operation of the integrity checking voltage Vic may be performed. Based on the nth integrity checking voltage Vicn provided from the integrity checking voltage generator 251a, charges may be transferred to the adjacent integrity checking capacitance Cicad and the adjacent integrity checking capacitance Cicad may be charged. The integrity checking charging voltage Vcic charged at the adjacent integrity checking capacitance Cicad during the first voltage write period Tf1 may be the nth integrity checking voltage Vicn. The n may be a natural number greater than or equal to 4.

The non-volatile memory device 20 performs a charge sharing operation between the adjacent integrity checking capacitance Cicad and the adjacent wordline capacitance Cwlad in response to the adjacent integrity checking capacitance Cicad being charged by the provision of the integrity checking voltage Vic (S130).

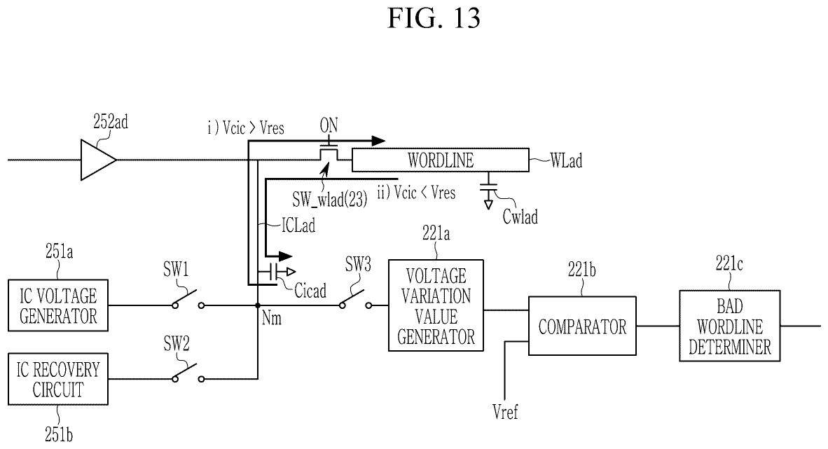

With additional reference to FIG. 13, during a first charge sharing period Tcs1 of the first period T1, the first switch SW1 is opened and an adjacent wordline switch SW_wlad is closed, so that a charge sharing operation between the adjacent integrity checking capacitance Cicad and the adjacent wordline capacitance Cwlad may be performed. As the adjacent wordline switch SW_wlad is closed, the adjacent integrity checking line ICLad and the adjacent wordline WLad are electrically connected, and charges between the adjacent integrity checking capacitance Cicad and the adjacent wordline capacitance Cwlad may be shared with each other.

If the integrity checking charging voltage Vcic is higher than the residual voltage Vresad of the adjacent wordline WLad, the charge accumulated in the adjacent integrity checking capacitance Cicad may move to the adjacent wordline capacitance Cwlad and interfere with the recovery operation of the adjacent wordline WLad. When the integrity checking charging voltage Vcic is higher than the residual voltage Vresad, the recovery operation of adjacent wordlines WLad during the charge sharing period may be slowed down and the discharge speed of the residual voltage Vresad may be slower. Depending on embodiments, the residual voltage Vresad of the adjacent wordline WLad may be kept constant due to the capacitance difference between the adjacent integrity checking capacitance Cicad and the adjacent wordline capacitance Cwlad during the charge sharing period.

When the residual voltage Vresad charged to the adjacent wordline capacitance Cwlad is higher than the integrity checking charging voltage Vcic, the charge accumulated in the adjacent wordline capacitance Cwlad may move to the adjacent integrity checking capacitance Cicad to enhance the recovery operation of the adjacent wordline WLad. When the residual voltage Vresad is higher than the integrity checking charging voltage Vcic, the recovery operation of adjacent wordlines WLad during the charge sharing period may be enhanced and the discharge speed of the residual voltage Vresad may be faster than the conventional speed.

Since the integrity checking charging voltage Vcic is higher than the residual voltage Vresad during the first charge sharing period Tcs1, the residual voltage Vresad of the adjacent wordline WLad may be kept constant. Additionally, during the first charge sharing period Tcs1, the integrity checking charging voltage Vcic charged at the adjacent integrity checking capacitance Cicad may decrease and become equal to the residual voltage Vresad.

The non-volatile memory device 20 generates a voltage variation value of the residual voltage Vresad for the adjacent wordline WLad in response to a charge sharing operation (S140).

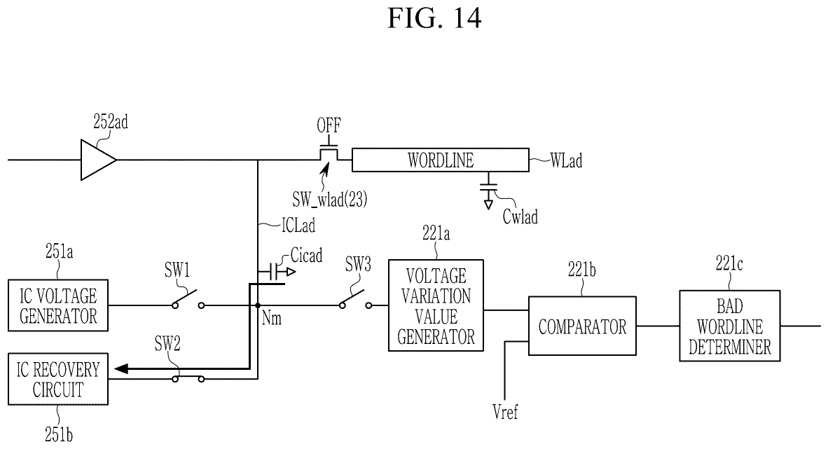

With additional reference to FIG. 14, during a first discharge period Tc1 of the first period T1, the adjacent wordline switch SW_wlad is opened and the second switch SW2 is closed, so that a discharge operation of the adjacent integrity checking capacitance Cicad may be performed. As the adjacent wordline switch SW_wlad is opened and the second switch SW2 is closed, the charge accumulated in the adjacent integrity checking capacitance Cicad may be discharged.

During the first discharge period Tc1, the adjacent integrity checking capacitance Cicad may be discharged and the integrity checking charging voltage Vcic may be a ground voltage.

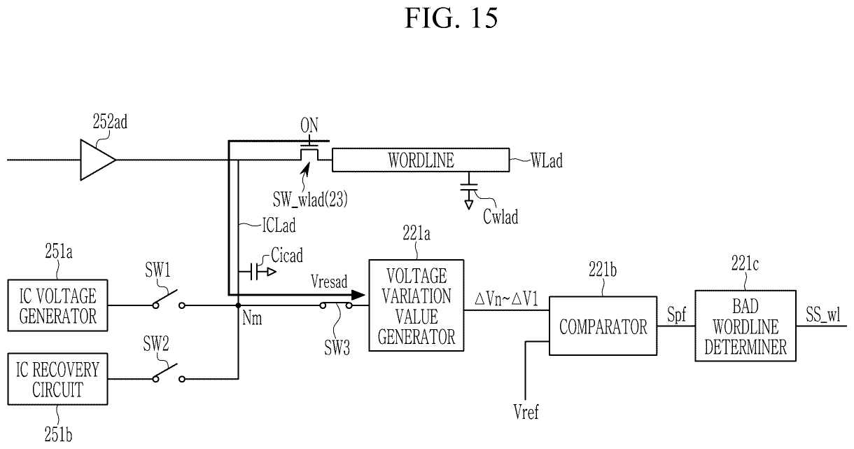

With additional reference to FIG. 15, during a first residual voltage reception period Trc1 of the first period T1, the second switch SW2 is opened and the adjacent wordline switch SW_wlad and the third switch SW3 are closed, so that a reception operation of the residual voltage Vresad for the adjacent wordline WLad may be performed. As the adjacent wordline switch SW_wlad and the third switch SW3 are closed, the voltage variation value generator 221a may be electrically connected to the adjacent wordline WLad through the adjacent integrity checking line ICLad and may receive the residual voltage Vresad of the adjacent wordline WLad.

The voltage variation value generator 221a may generate an nth voltage variation value ΔVn, which is a voltage variation value between the residual voltage Vresad received from the first residual voltage reception period Trc1 of the first period T1 and the residual voltage Vresad received before the first period T1. For example, the nth voltage variation value ΔVn may be the voltage variation value of the residual voltage Vresad between time t1 and time t2. The nth voltage variation value ΔVn may be generated based on the write operation of the nth integrity checking voltage Vicn during the first voltage write period Tf1 and the charge sharing operation of the adjacent wordline capacitance Cwlad during the first charge sharing period Tcs1.

The generated nth voltage variation value ΔVn may be provided to the comparator 221b, and the comparator 221b may compare the nth voltage variation value ΔVn with the reference voltage Vref and output the pass/fail signal Spf corresponding to the nth voltage variation value ΔVn. The comparator 221b may output a pass signal if the nth voltage variation value ΔVn is less than the reference voltage Vref, and the comparator 221b may output a fail signal if the nth voltage variation value ΔVn is greater than the reference voltage Vref. Referring to FIG. 9 and FIG. 16 as examples, in response to the nth voltage variation value ΔVn being less than the reference voltage Vref, the comparator 221b may output the pass/fail signal Spf, which is a pass signal P.

The non-volatile memory device 20 checks whether the provided integrity checking voltage Vic is the lowest voltage (S150).

If the integrity checking voltage Vic previously provided by the integrity checking voltage generator 251a is not the lowest voltage, the non-volatile memory device 20 may repeatedly perform steps S160 and S130 to S150 during an integrity-determination operation for the adjacent integrity checking line ICLad. According to an embodiment, the non-volatile memory device 20 may perform step S160 and sequentially perform steps S130 to S150.

After the nth integrity checking voltage Vicn is provided by the integrity checking voltage generator 251a, the non-volatile memory device 20 may repeatedly perform a write operation of the integrity checking voltage Vic, a charge sharing operation between the adjacent integrity checking capacitance Cicad and the adjacent wordline capacitance Cwlad, a discharge operation of the adjacent integrity checking capacitance Cicad, and a reception operation of the residual voltage Vresad for the adjacent wordline WLad for each of second to Nth sections T2 to TN corresponding to steps S160 and S130 to S150.

If the previously provided integrity checking voltage Vic is the lowest voltage, the non-volatile memory device 20 may perform step S170.

In step S150 of FIG. 8, the non-volatile memory device 20 determines the subsequent operation of step S140 based on whether the provided integrity checking voltage Vic is the lowest voltage, but according to an embodiment, the non-volatile memory device 20 may determine the subsequent operation of step S140 in response to the pass/fail signal Spf based on the provided integrity checking voltage Vic.

For example, the non-volatile memory device 20 may repeatedly perform steps S160 and S130 to S150 during an integrity-determination operation for the adjacent integrity checking line ICLad if the pass/fail signal Spf based on the integrity checking voltage Vic is the pass signal P.

In example embodiments, the non-volatile memory device 20 may perform step S170 if the pass/fail signal Spf based on the integrity checking voltage Vic is a fail signal F. For example, in step S140, the non-volatile memory device 20 may output the pass/fail signal Spf, which is a fail signal F, in response to the voltage variation value ΔV being greater than the reference voltage Vref, and then perform steps S170 to S200 without step S150.

If the provided integrity checking voltage Vic is not the lowest voltage, the integrity checking voltage generator 251a provides a one-step lower integrity checking voltage Vic to the adjacent integrity checking line ICLad (S160). In example embodiments, even when the provided integrity checking voltage Vic is not the lowest voltage, the non-volatile memory device 20 may perform steps S170 to S200 in response to the fail signal F without repeating steps S160 and S130 to S150.

Referring to FIG. 9 as an example, at time tx after the time t1, the integrity checking voltage generator 251a may provide a k+1th integrity checking voltage Vick+1 lower than the nth integrity checking voltage Vicn to the adjacent integrity checking line ICLad. The x is a natural number greater than 1 and less than n, and the k is a natural number greater than 2 and less than n−1.

After the time tx, the non-volatile memory device 20 may perform a write operation of the integrity checking voltage Vic, a charge sharing operation between the adjacent integrity checking capacitance Cicad and the adjacent wordline capacitance Cwlad, a discharge operation of the adjacent integrity checking capacitance Cicad, and a reception operation of the residual voltage Vresad for the adjacent wordline WLad during each of an xth voltage write period Tfx, an xth charge sharing period Tcsx, an xth discharge period Tcx, and an xth residual voltage reception period Trcx within an xth period Tx. Each of the xth voltage write period Tfx, the xth charge sharing period Tcsx, the xth discharge period Tcx, and the xth residual voltage reception period Trcx may correspond to each of the first voltage write period Tf1, the first charge sharing period Tcs1, the first discharge period Tc1, and the first residual voltage reception period Trc1 within the first period T1.

During the xth voltage write period Tfx, the adjacent integrity checking capacitance Cicad may be charged based on the k+1th integrity checking voltage Vick+1 provided from the integrity checking voltage generator 251a. The integrity checking charging voltage Vcic charged at the adjacent integrity checking capacitance Cicad during the xth voltage write period Tfx may be the k+1th integrity checking voltage Vick+1. During the xth charge sharing period Tcsx, the charges between the adjacent integrity checking capacitance Cicad and the adjacent wordline capacitance Cwlad are shared with each other, and since the integrity check charging voltage Vcic is higher than the residual voltage Vresad, the residual voltage Vresad of the adjacent wordline WLad may be kept constant. Additionally, during the xth charge sharing period Tcsx, the integrity checking charging voltage Vcic charged at the adjacent integrity checking capacitance Cicad may decrease and become equal to the residual voltage Vresad. During the xth discharge period Tcx, the adjacent integrity checking capacitance Cicad may be discharged and the integrity checking charging voltage Vcic may be a ground voltage. During the xth residual voltage reception period Trcx, a reception operation of the residual voltage Vresad for the adjacent wordline WLad is performed, causing the voltage variation value generator 221a to generate a k+1th voltage variation value ΔVk+1 corresponding to the k+1th integrity checking voltage Vick+1, and the comparator 221b may compare the k+1th voltage variation value ΔVk+1 with the reference voltage Vref, and output the pass/fail signal Spf, which is the pass signal P, in response to the k+1th voltage variation value ΔVk+1 being less than the reference voltage Vref. For example, the k+1th voltage variation value ΔVk+1 may be a voltage variation value of the residual voltage Vresad between the time tx and the time tx+1.

At the time tx+1 after the time tx, the integrity checking voltage generator 251a may provide the kth integrity checking voltage Vick that is less than the k+1th integrity checking voltage Vick+1 to the adjacent integrity checking line ICLad.

After the time tx+1, the non-volatile memory device 20 may perform a write operation of the integrity checking voltage Vic, a charge sharing operation between the adjacent integrity checking capacitance Cicad and the adjacent wordline capacitance Cwlad, a discharge operation of the adjacent integrity checking capacitance Cicad, and a reception operation of the residual voltage Vresad for the adjacent wordline WLad during each of an x+1th voltage write period Tfx+1, an x+1th charge sharing period Tcsx+1, an x+1th discharge period Tcx+1, and an x+1th residual voltage reception period Trcx+1 within an x+1th period Tx+1. Each of the x+1th voltage write period Tfx+1, the x+1th charge sharing period Tcsx+1, the x+1th discharge period Tcx+1, and the x+1th residual voltage reception period Trcx+1 may correspond to each of the first voltage write period Tf1, the first charge sharing period Tcs1, the first discharge period Tc1, and the first residual voltage reception period Trc1 within the first period T1.

During the x+1th voltage write period Tfx+1, the adjacent integrity checking capacitance Cicad may be charged based on the kth integrity checking voltage Vick provided from the integrity checking voltage generator 251a. The integrity checking charging voltage Vcic charged at the adjacent integrity checking capacitance Cicad during the x+1th voltage write period Tfx+1 may be the kth integrity checking voltage Vick. During the x+1th charge sharing period Tcsx+1, the charge between the adjacent integrity checking capacitance Cicad and the adjacent wordline capaci capacitance tor Cwlad is shared with each other, and since the residual voltage Vresad is higher than the integrity checking charging voltage Vcic, the residual voltage Vresad of the adjacent wordline WLad may be accelerated and lowered. Additionally, the integrity checking charging voltage Vcic charged at the adjacent integrity checking capacitance Cicad during the x+1th charge sharing period Tcsx+1 may be lowered together. During the x+1th discharge period Tcx+1, the adjacent integrity checking capacitance Cicad may be discharged and the integrity checking charging voltage Vcic may be a ground voltage. During the x+1th residual voltage reception period Trcx, a reception operation of the residual voltage Vresad for the adjacent wordline WLad is performed, causing the voltage variation value generator 221a to generate the kth voltage variation value ΔVk corresponding to the kth integrity checking voltage Vick, and the comparator 221b may compare the kth voltage variation value ΔVk with the reference voltage Vref, and output the pass/fail signal Spf, which is the fail signal F, in response to the kth voltage variation value ΔVk being greater than the reference voltage Vref. For example, the kth voltage variation value ΔVk may be a voltage variation value of the residual voltage Vresad between the time tx+1 and the time tx+2.

At time tn after the time tx+1, the integrity checking voltage generator 251a may provide a first integrity checking voltage Vic1 that is lower than the kth integrity checking voltage Vick and is the lowest voltage among a plurality of integrity checking voltages Vic1 to Vicn to the adjacent integrity checking line ICLad.

After the time tn, the non-volatile memory device 20 may perform a write operation of the integrity checking voltage Vic, a charge sharing operation between the adjacent integrity checking capacitance Cicad and the adjacent wordline capacitance Cwlad, a discharge operation of the adjacent integrity checking capacitance Cicad, and a reception operation of the residual voltage Vresad for the adjacent wordline WLad during each of an nth voltage write period Tfn, an nth charge sharing period Tcsn, an nth discharge period Tcn, and an nth residual voltage reception period Trcn within an nth period Tn. Each of the nth voltage write period Tfn, the nth charge sharing period Tcsn, the nth discharge period Tcn, and the nth residual voltage reception period Trcn may correspond to each of the first voltage write period Tf1, the first charge sharing period Tcs1, the first discharge period Tc1, and the first residual voltage reception period Trc1 within the first period T1.

During the nth voltage write period Tfn, the adjacent integrity checking capacitance Cicad may be charged based on the first integrity checking voltage Vic1 provided by the integrity checking voltage generator 251a. The integrity checking charging voltage Vcic charged at the adjacent integrity checking capacitance Cicad during the nth voltage write period Tfn may be the first integrity checking voltage Vic1. During the nth charge sharing period Tcsn, the charge between the adjacent integrity checking capacitance Cicad and the adjacent wordline capacitance Cwlad is shared with each other, and since the residual voltage Vresad is higher than the integrity checking charging voltage Vcic, the residual voltage Vresad of the adjacent wordline WLad may be accelerated and lowered. Additionally, during the nth charge sharing period Tcsn, the integrity checking charging voltage Vcic charged at the adjacent integrity checking capacitance Cicad may increase to become equal to the residual voltage Vresad, and the amount of power accumulation of the adjacent integrity checking capacitance Cicad may increase. During the nth discharge period Tcn, the adjacent integrity checking capacitance Cicad may be discharged and the integrity checking charging voltage Vcic may be ground voltage. During the nth residual voltage reception period Trcn, a reception operation of the residual voltage Vresad for the adjacent wordline WLad is performed, causing the voltage variation value generator 221a to generate a first voltage variation value ΔV1 corresponding to the first integrity checking voltage Vic1, and the comparator 221b may compare the first voltage variation value ΔV1 with the reference voltage Vref, and output the pass/fail signal Spf, which is the fail signal F, in response to the first voltage variation value ΔV1 being greater than the reference voltage Vref. For example, the first voltage variation value ΔV1 may be a voltage variation value of the residual voltage Vresad between the time tn and the time tn+1.

The bad wordline determiner 221c detects a determination residual voltage Vresd through the pass/fail signal Spf based on a plurality of voltage variation values ΔV1 to ΔVn (S170).

The bad wordline determiner 221c may receive the pass/fail signal Spf based on the plurality of voltage variation values ΔV1 to ΔVn, and select one of the plurality of integrity checking voltages Vic1 to Vicn corresponding to the plurality of voltage variation values ΔV1 to ΔVn based on the pass/fail signal Spf to detect as the determination residual voltage Vresd.

Referring to FIG. 16 as an example, the bad wordline determiner 221c may receive the pass/fail signal Spf based on the plurality of voltage variation values ΔV1 to ΔVn, and detect the k+1th integrity checking voltage Vick+1 as the determination residual voltage Vresd based on the pass/fail signal Spf, which is the last received pass signal P.

According to an embodiment, the bad wordline determiner 221c may select one of the plurality of integrity checking voltages Vic1 to Vicn based on the pass/fail signal Spf, which is the first received fail signal F, and detect it as the determination residual voltage Vresd.

The determination residual voltage Vresd may be the integrity checking voltage Vic corresponding to an initial residual voltage Vresi of the adjacent wordline WLad at the time t1, which is the integrity determination time. Due to the difference in capacitance between the adjacent integrity checking capacitance Cicad and the adjacent wordline capacitance Cwlad, the residual voltage Vresad of the adjacent wordline WLad may be kept constant while charges are shared through the adjacent integrity checking capacitance Cicad charged by the relatively high-voltage integrity checking voltage Vic, and the residual voltage Vresad of the adjacent wordline WLad may be rapidly decreased while charges are shared through the adjacent integrity checking capacitance Cicad charged by the relatively low-voltage integrity checking voltage Vic. The non-volatile memory device 20 may detect the initial residual voltage Vresi at the time t1 through the variation characteristics of the residual voltage Vresad as described above.

The bad wordline determiner 221c determines the integrity of the adjacent wordline WLad by comparing the detected determination residual voltage Vresd with the threshold voltage Vth (S180).

The bad wordline determiner 221c determines the adjacent wordline WLad as normal if the detected determination residual voltage Vresd is less than the threshold voltage Vth (S190).

The defective wordline determiner 221c determines the adjacent wordline WLad as bad if the detected determination residual voltage Vresd is greater than the threshold voltage Vth and outputs the wordline status signal SS_wl (S200).

Referring to FIG. 16 as an example, when the determination residual voltage Vresd, which is the K+1th integrity checking voltage Vick+1, is greater than the threshold voltage Vth, the bad wordline determiner 221c may determine the adjacent wordline WLad as bad. The non-volatile memory device may provide the wordline status signal SS_wl for the adjacent wordline WLad to the storage controller 30 based on the determination of bad. In FIG. 16, it is assumed that a level of the threshold voltage Vth may be between the integrity checking voltage Vick−1 and the integrity checking voltages Vic1.

The non-volatile memory device 20 may directly and internally detect the residual voltage of the wordline through steps S110 to S200. The non-volatile memory device 20 directly detects the residual voltage of a wordline, and does not require time to leave the residual voltage to check whether a disturbance has occurred in an adjacent wordline. The non-volatile memory device 20 may quickly internally determine the recovery integrity of a wordline and efficiently screen out bad wordlines.

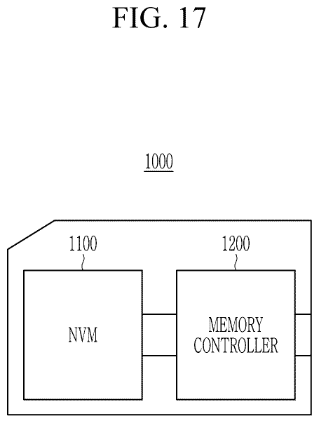

FIG. 17 is a block diagram illustrating a data storage device, which is an example of a storage device according to an embodiment.

Referring to FIG. 17, a data storage device 1000 may include a non-volatile memory device 1100 and a memory controller 1200.

The non-volatile memory device 1100 directly detects the residual voltage of a wordline at the time of integrity determination as described in FIGS. 1 to 16, and does not require time to leave the residual voltage to check whether a disturbance has occurred in an adjacent wordline. The non-volatile memory device 1200 may quickly internally determine the recovery integrity of a wordline and efficiently screen out bad wordlines.

The memory controller 1200 may control program/read/erase operations of the non-volatile memory device 1100 in response to a request from outside.

The data storage device 1000 may configure a memory card device, an SSD device, a multimedia card device, an SD device, a memory stick device, a hard disk drive device, a hybrid drive device, or a universal serial bus flash device. For example, the data storage device 1000 may configure a card for use with user devices such as a digital camera, a personal computer, and the like.

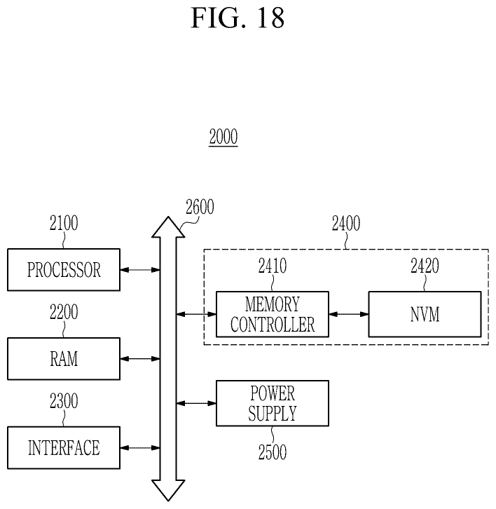

FIG. 18 is a block diagram illustrating a computing system including a storage device according to an embodiment.

Referring to FIG. 18, a computing system 2000 may include a processor 2100, a RAM 2200, an interface device 2300, a memory system 2400, a power supply device 2500, and a bus 2600.

The processor 2100, the RAM 2200, the interface device 2300, the memory system 2400, and the power supply device 2500 may be coupled to each other through the bus 2600. The bus 2600 corresponds to the path through which data is moved.

The processor 2100 may include at least one of a microprocessor, a digital signal processor, a microcontroller, and logic devices capable of performing functions similar thereto.

The RAM 2200 may be used as working memory to improve the performance of the processor 2100. The interface device 2300 may perform a function of transmitting data to a communication network or receiving data from a communication network.

The interface device 2300 may be wired or wireless. For example, the interface device 2300 may include an antenna or a wired or wireless transceiver.

The memory system 2400 may store data and/or instructions, etc. The memory system 2400 may include a memory controller 2410 and a non-volatile memory device 2420.

The memory controller 2410 may control program/read/erase operations of the non-volatile memory device 2420. The non-volatile memory device 2420 may include a plurality of non-volatile memory chips. The non-volatile memory device 2420 directly detects the residual voltage of a wordline at the time of integrity checking as described in FIGS. 1 to 16, and does not require a time for leaving the residual voltage to check whether a disturbance has occurred in an adjacent wordline. The non-volatile memory device 2420 may quickly internally determine the recovery integrity of a wordline and efficiently screen out bad wordlines.

The power supply 2500 may supply operating power to the processor 2100, the RAM 2200, the interface device 2300, and the memory system 2400.

The computing system 2000 may be applied to a personal digital assistant (PDA), a portable computer, a web tablet, a wireless phone, a mobile phone, a digital music player, a memory card, or any electronic product capable of transmitting and/or receiving information in a wireless environment.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the present invention as set forth in the appended claims.

What is claimed is:

1. A non-volatile memory device, comprising:
a memory cell array including a plurality of first memory cells connected to a first wordline;
a voltage generator configured to provide a plurality of integrity checking voltages to a first integrity checking line electrically connected to the first wordline; and
a control logic circuit configured to receive a residual voltage of the first wordline from the first integrity checking line in response to provision of the plurality of integrity checking voltages to the first integrity checking line.

2. The non-volatile memory device of claim 1, wherein:
the memory cell array further includes a plurality of second memory cells connected to a second wordline disposed adjacent to the first wordline, and
the voltage generator is configured to provide the plurality of integrity checking voltages to the first integrity checking line in response to completion of a memory operation for the plurality of second memory cells.

3. The non-volatile memory device of claim 2, wherein:
the plurality of integrity checking voltages includes sequentially higher first to nth integrity checking voltages, and
the voltage generator is configured to preferentially provide the nth integrity checking voltage among the plurality of integrity checking voltages to the first integrity checking line.

4. The non-volatile memory device of claim 3, wherein the voltage generator is configured to provide the first to nth integrity checking voltages to the first integrity checking line in the order of the nth integrity checking voltage to the first integrity checking voltage.

5. The non-volatile memory device of claim 2, further comprising:
a voltage generator configured to generate a pass voltage,
wherein the memory operation is one of a read operation or a program operation for the plurality of second memory cells, and
wherein the voltage generator is configured to provide the pass voltage to the first wordline during at least a part of the memory operation.

6. The non-volatile memory device of claim 1, wherein the non-volatile memory device is configured to perform a charge sharing operation between a capacitance of the first integrity checking line and a capacitance of the first wordline in response to the provision of the plurality of integrity checking voltages to the first integrity checking line.

7. The non-volatile memory device of claim 6, wherein:
the range of the capacitance of the first integrity checking line and the capacitance of the first wordline is 1 to x, and
the x is a real number in the range of 75 to 125.

8. The non-volatile memory device of claim 6, wherein:
the plurality of integrity checking voltages includes a first integrity checking voltage and a second integrity checking voltage lower than the first integrity checking voltage,
the non-volatile memory device is configured to perform:
a first charge sharing operation between the capacitance of the first integrity checking line and the capacitance of the first wordline in response to the provision of the first integrity checking voltage to the first integrity checking line, and
a second charge sharing operation between the capacitance of the first integrity checking line and the capacitance of the first wordline in response to the provision of the second integrity checking voltage to the first integrity checking line.

9. The non-volatile memory device of claim 8, wherein:
the control logic circuit is configured to generate a first voltage variation value of the residual voltage in response to a result of the first charge sharing operation,
the control logic circuit is configured to generate a second voltage variation value of the residual voltage in response to a result of the second charge sharing operation, and
the second voltage variation value is greater than the first voltage variation value.

10. The non-volatile memory device of claim 9, wherein the amount of power accumulation of the first integrity checking capacitance increases in response to the provision of the first integrity checking voltage to the first integrity checking line.

11. The non-volatile memory device of claim 1, wherein the control logic circuit includes a voltage variation value generator configured to generate a voltage variation value between a previous residual voltage of the first wordline received before provision of a first integrity checking voltage among the plurality of integrity checking voltages and a residual voltage of the first wordline received after provision of the first integrity checking voltage.

12. The non-volatile memory device of claim 11, wherein the voltage variation value generator includes:
an operational amplifier configured to output the voltage variation value, and
a sample hold circuit configured to maintain the previous residual voltage and provide the previous residual voltage to the operational amplifier.

13. The non-volatile memory device of claim 11, wherein the control logic circuit further includes a comparator configured to:
compare the voltage variation value with a predetermined reference voltage, and
output a pass/fail signal in response to a result of the comparison.

14. A method of operating a non-volatile memory device, the method comprising:
performing a memory operation for a target wordline;
providing a first integrity checking voltage to an integrity checking line electrically connected to an adjacent wordline disposed adjacent to the target wordline, in response to completion of the memory operation;
performing a first charge sharing operation for sharing charge between a capacitance of the adjacent wordline and a capacitance of the integrity checking line accumulated by the first integrity checking voltage;
generating a first voltage variation value of a residual voltage of the adjacent wordline in response to the first charge sharing operation; and
detecting a determination residual voltage for the adjacent wordline based on the first voltage variation value.

15. The method of claim 14, further comprising:
determining the integrity of the adjacent wordline based on the determination residual voltage and a predetermined threshold voltage.

16. The method of claim 15, further comprising:
outputting a status signal of the adjacent wordline to outside the non-volatile memory device in response to a determination of badness of the adjacent wordline.

17. The method of claim 14, further comprising:
providing a second integrity checking voltage lower than the first integrity checking voltage to the integrity checking line after providing the first integrity checking voltage;
performing a second charge sharing operation for sharing charges between the capacitance of the adjacent wordline and the capacitance of the integrity checking line accumulated by the second integrity checking voltage; and
generating a second voltage variation value in response to the second charge sharing operation,
wherein the determination residual voltage is detected based on the first and second voltage variation values.

18. The method of claim 14, wherein the generating of the first voltage variation value includes:
discharging the capacitance of the integrity checking line and receiving a residual voltage of the adjacent wordline.

19. A storage device, comprising:
a non-volatile memory device including:
a memory cell array including a plurality of first memory cells connected to a first wordline, and
a control logic circuit configured to detect a determination residual voltage for the first wordline through a first integrity checking line electrically connected to the first wordline, and output a status signal for the first wordline based on the determination residual voltage; and
a storage controller configured to perform a replacement operation for the first wordline based on the status signal.

20. The storage device of claim 19, wherein:
the non-volatile memory device further includes a voltage generator configured to provide a plurality of integrity checking voltages to the first integrity checking line, and
the control logic circuit is configured to receive a residual voltage of the first wordline from the first integrity checking line and detect the determination residual voltage based on a voltage variation value of the residual voltage, in response to the provision of the plurality of integrity checking voltages to the first integrity checking line.
